(19) United States
(12) Patent Application Publication
(10) Pub. No.: US 2016/0149063 A1
(43) Pub. Date: May 26, 2016

(54) Backsheets/Frontsheets Having Improved Adhesion to Encapsulants and Photovoltaic Modules Made Therefrom

(71) Applicant: DOW GLOBAL TECHNOLOGIES LLC, Midland, MI (US)

(72) Inventors: Huiqing Zhang, Midland, MI (US); Aude Pochon, Richterswil (CH); John A. Naumovitz, Midland, MI (US); Rudolf J. Koopmans, Einsiedeln (CH); Ray E. Drumright, Midland, MI (US)

(21) Appl. No.: 14/901,342

(22) PCT Filed: Jun. 13, 2014
(86) PCT No.: PCT/US2014/042238

§ 371 Date: Dec. 28, 2015

Related U.S. Application Data
(60) Provisional application No. 61/840,566, filed on Jun. 28, 2013.

(51) Int. Cl. H01L 31/048; B32B 7/10; B32B 7/12; B32B 27/30; B32B 27/34; B32B 27/36; B32B 27/32; H01L 31/049; B32B 27/08

(52) U.S. Cl. CPC H01L 31/0481; H01L 31/049; B32B 7/10; B32B 7/12; B32B 27/08; B32B 27/34; B32B 27/36; B32B 27/322; B32B 27/304; B32B 2250/24; B32B 2255/10; B32B 2255/26; B32B 2457/12

(57) ABSTRACT

A backsheet or frontsheet having an outer layer with a melting temperature greater than or equal to 150° C. includes at least one surface comprising a surface modification to improve adhesion between the backsheet or frontsheet and an encapsulant. The adhesion of the backsheet or frontsheet and encapsulant, after lamination, is at least 20 N/cm, preferably at least 40 N/cm or no adhesion failure. More preferably, the adhesion is at least 20 N/cm, even more preferably 40 N/cm or no adhesion failure, before and after 1,000 hours, preferably 2,000 hours, of damp heat aging at 85° C. and 85% humidity.

### FIELD OF THE INVENTION

In one aspect the invention relates to backsheets/frontsheets having a surface modification to improve adhesion between the backsheets/frontsheets and encapsulants in photovoltaic modules, while in another aspect, the invention relates to methods of increasing the functionality of backsheets/frontsheets to improve adhesion with encapsulants.

### BACKGROUND OF THE INVENTION

Photovoltaic (PV) modules typically comprise, in sequence, (i) a light-receiving and transmitting top sheet or cover sheet film, usually comprising glass or polymer films (frontsheet), (ii) a front encapsulant, (iii) photovoltaic cells, (iv) a rear encapsulant, and (v) a backsheet. Several adhesion mechanisms are at work between the encapsulant and the backsheet or frontsheet. Covalent bonding, Van der Waals forces, polar-polar interactions, intermolecular diffusion/welding and mechanic interlocking at the interface of the substrates all work together to adhere the encapsulant to the front- and backsheets.

Encapsulants are primarily polyolefin-based or based on ethylene-vinyl acetate (EVA). Polyolefin-based encapsulants, such as encapsulants comprising linear low density polyethylene (LLDPE) with minimal silane functionality, have several advantages over EVA encapsulants. Polyolefin-based encapsulants have better electrical resistivity, high moisture resistance and long term reliability. However, due to low surface energy and low functionality, polyolefin-based encapsulants have poor adhesion to some backsheets/frontsheet, particularly those containing a polyimide or fluoropolymer seal layer (layer to be adhered to encapsulant). Such backsheets include polyamide/polyamide/polyamide (AAA) backsheets, poly(vinyl fluoride)/polyethylene terephthalate (PET)/polyamide (TPA) backsheets, fluoropolymer/polyethylene terephthalate/polyamide (FPA) backsheets, polyamide/PET/polyamide (APA) backsheets, Tedlar (or poly(vinyl fluoride))/(PET)/Tedlar (or poly(vinyl floride)) (TPT) backsheets, Kynar (or poly(vinylidene fluoride))/PET/Kynar (or poly(vinylidene fluoride)) (KPK) backsheets, fluoropolymer/PET/fluoropolymer (FPF). Frontsheets having poor adhesion to polyolefin-based encapsulants may include those containing fluoropolymers, such as poly(ethylene-co-tetrafluoroethylene) (ETFE), fluorinated ethylene propylene (FEP), and poly(vinylidene fluoride) (PVDF); polyimide; and polyethylene terephthalate /polyethylene naphthalate (PET/PEN). The adhesion between polyolefin-based encapsulants and such backsheets/frontsheet may be especially poor after long term damp and heat aging. For PV modules, generally the adhesion of encapsulants to backsheets/frontsheets is at least 20 N/cm, preferably 40 N/cm or no adhesion failure, before and after 1000 hours, preferably 2000 hours, of damp/heat aging at 85° C. and 85% humidity.

Although the surfaces of commercially available backsheets/frontsheets are treated by producers to include some functionality, it is not sufficient to achieve the required adhesion with polyolefin-based encapsulants. A need remains for backsheets/frontsheets having improved adhesion with polyolefin-based encapsulants, and specifically AAA, TPA, FPA, APA, TPT, KPK and FPF backsheets and ETFE-, FEP-, PVDF-, PET/PEN-, and polyimide-containing frontsheets having an adhesion to polyolefin-based encapsulants of at least 20 N/cm, preferably 40 N/cm or no adhesion failure, before and after 1000 hours, preferably 2000 hours, of damp/heat aging at 85° C. and 85% humidity.

### SUMMARY OF THE INVENTION

In one embodiment, the invention is a multilayer film having an outer layer with a melting temperature greater than or equal to 150° C. and at least one surface comprising a surface modification. The surface containing the surface modification is configured to be in adhering contact with a polyolefin-based encapsulant film. The adhesion of the multilayer film and encapsulant, after lamination, is at least 20 N/cm, preferably at least 40 N/cm or no adhesion failure. More preferably, the adhesion is at least 20 N/cm, even more preferably 40 N/cm or no adhesion failure, before and after 1,000 hours, more preferably 2,000 hours, of damp heat aging at 85° C. and 85% humidity.

In another embodiment, the invention is an electronic device comprising a polyolefin-based encapsulant and at least one of a backsheet or frontsheet having a surface with a surface modification. The modified surface of the backsheet or frontsheet is configured to be in adhering contact with the polyolefin-based encapsulant. The adhesion of the backsheet or frontsheet and encapsulant, after lamination, is at least 20 N/cm, preferably at least 40 N/cm or no adhesion failure. More preferably, the adhesion is at least 20 N/cm, even more preferably 40 N/cm or no adhesion failure, before and after 1,000 hours, preferably 2,000 hours, of damp heat aging at 85° C. and 85% humidity

In another embodiment, the invention is a method for improving the adhesion between a polyolefin-based encapsulant and a backsheet or frontsheet comprising the step of modifying a surface of the backsheet or frontsheet to introduce at least one functional molecule or functional group to the surface to increase covalent bonding or intermolecular diffusion between the encapsulant and the backsheet or frontsheet. The adhesion of the surface-modified backsheet or frontsheet and the encapsulant, after lamination, is at least 20 N/cm, preferably at least 40 N/cm or no adhesion failure. More preferably, the adhesion is at least 20 N/cm, even more preferably 40 N/cm or no adhesion failure, before and after 1,000 hours, preferably 2,000 hours, of damp heat aging at 85° C. and 85% humidity.

### DETAILED DESCRIPTION

Definitions

The numerical ranges in this disclosure are approximate, and thus may include values outside of the range unless otherwise indicated. Numerical ranges include all values from and including the lower and the upper values, in increments of one unit, provided that there is a separation of at least two units between any lower value and any higher value. As an example, if a compositional, physical or other property, such as, for example, molecular weight, viscosity, melt index, etc., is from 100 to 1,000, it is intended that all individual values, such as 100, 101, 102, etc., and sub ranges, such as 100 to 144, 155 to 170, 197 to 200, etc., are expressly enumerated. For ranges containing values which are less than one or containing fractional numbers greater than one (e.g., 1.1, 1.5, etc.), one unit is considered to be 0.0001, 0.001, 0.01 or 0.1, as appropriate. For ranges containing single digit numbers less than ten (e.g., 1 to 5), one unit is typically considered to be 0.1. These are only examples of what is specifically intended, and all possible combinations of numerical values between the lowest value and the highest value enumerated are to be considered to be expressly stated in this disclosure. Unless stated to the contrary, implicit from the context, or customary in the art, all parts and percentages are by weight, and all test methods are current as of the filing date of this disclosure.

As used herein, the terms “adhering contact” and “in adhering contact” mean that one surface of one layer or film and one surface of another layer or film are in touching and binding contact to one another such that the layers or films are not initially separable without using force or damaging one or both layers or films. “Adhering contact” and “in adhering contact” are also used to indicate that layers or films are intended to be inseparable (such as after lamination), even if delamination of the layers occurs with little force and damage.

As used herein, the term “backsheet” refers to the outermost layer of a PV module. A backsheet is typically a multi-layer film made by lamination or co-extrusion.

As used herein, the terms “coating” is used to refer to a layer applied to the surface of a film, such as an encapsulant, backsheet or frontsheet. A coating will have a measurable thickness.

“Comprising”, “including”, “having” and like terms are not intended to exclude the presence of any additional component, step or procedure, whether or not the same is specifically disclosed. In order to avoid any doubt, all processes claimed through use of the term “comprising” may include one or more additional steps, pieces of equipment or component parts, and/or materials unless stated to the contrary. In contrast, the term, “consisting essentially of” excludes from the scope of any succeeding recitation any other component, step or procedure, excepting those that are not essential to operability. The term “consisting of” excludes any component, step or procedure not specifically delineated or listed. The term “or”, unless stated otherwise, refers to the listed members individually as well as in any combination.

As used herein, the term “corresponding films” refers to the film pairs backsheet/encapsulant or frontsheet/encapsulant.

As used herein, the term “electronic device” refers to any device having an electronic component enclosed between at least two film layers. Electronic devices include, for example, liquid crystal panels, solar cells, photovoltaic cells, photovoltaic modules, electro-luminescent devices and plasma display units.

As used herein, the term “encapsulant” refers to polyolefin-based films used as encapsulation layers in PV modules.

As used herein, the term “frontsheet” refers to a light-receiving and transmitting layer of a PV module which is directly exposed to sunlight.

As used herein, the term “functionalized” refers to a film having functional groups, such as hydroxyl, amine, carboxylic acid, ester and silane groups, introduced onto at least one surface.

The term, “olefin-based polymer,” as used herein, refers to a polymer that comprises, in polymerized form, a majority amount of olefin monomer, for example ethylene or propylene (based on the weight of the polymer), and optionally may comprise one or more comonomers.

As used herein, the term “surface modification” refers to a change in the surface functionality of a backsheet, frontsheet or encapsulant. A surface modification can be a chemical or physical change in the surface of a backsheet, frontsheet, or encapsulant film and results in improved adhesion between the modified backsheet, frontsheet or encapsulant and corresponding film compared to an identical though unmodified corresponding film pair.

Surface-Modified Backsheets, Frontsheets and Encapsulanis

Generally, there are four adhesion mechanisms between two substrates which affect the adhesion strength: (1) covalent bonding, (2) Van der Waals force and polar-polar interactions, (3) intermolecular diffusion/welding, and (4) mechanic interlocking at the interface. To have an adhesion of at least 40 N/cm (or no adhesion failure) after 1000 hours, and preferably after 2000 hours of damp heat aging at 85° C. and 85% humidity, the bonding at the interface of an encapsulant and backsheet or encapsulant and frontsheet must include either covalent bonds and/or intermolecular welding.

Polyolefin-based encapsulants and backsheet and frontsheets, especially AAA, TPT and KPK backsheets and ETFE-containing frontsheets, for example, have limited surface functionality. The functional groups present in the backsheets/frontsheets do not interact with the functional groups of the polyolefin-based encapsulant. In order to increase covalent bonding, specific functional groups must be introduced to the surface of the backsheet/frontsheet, encapsulant or both. There is also little intermolecular diffusion/welding between polyolefin-based encapsulants and some backsheets/frontsheets. Some frontsheets and backsheets, especially, for example, AAA, TPT and KPK backsheets, melt at temperatures above the temperatures used during lamination. With no melting, intermolecular diffusion is extremely slow. Lamination temperatures range from 140-160° C., and most backsheets and frontsheets containing a polyimide or fluoropolymer seal layer have melting temperatures greater than or equal to 150° C.

In one embodiment, a multilayer film, such as a backsheet, frontsheet or encapsulant comprises at least one surface with a surface modification. The modified surface is configured to be in adhering contact with either a polyolefin-based in encapsulant (i.e., if the modified film is a backsheet or frontsheet) or a backsheet or frontsheet (i.e., if the modified film is an encapsulant). The adhesion between the films after lamination is at least 20 N/cm, preferably at least 40 N/cm or no adhesion failure, before and after 1,000 hours, preferably 2,000 hours, of damp heat aging at 85° C. and 85% humidity.

In one embodiment, the surface modification is at least one functional group or functional molecule. A functional group or functional molecule may be applied as a coating or through atmospheric plasma treatment. The specific functional groups or functional molecules used to modify the backsheets, frontsheets and encapsulants will vary based on the functionality of the corresponding surface to which the backsheet, frontsheet or encapsulant will be laminated.

In a preferred embodiment, the encapsulant is a polyolefin-based encapsulant containing minimal (less than 2%) vinyl-trimethylsiloxane, and the backsheet or frontsheet is selected from an AAA, TPT or KPK backsheet or an ETFE-containing frontsheet. When the encapsulant is modified, the functional groups incorporated onto the surface of the encapsulant include amine, carboxylic acid, ester, maleic anhydride, epoxy and peroxide groups. The specific functional group added will depend on what functional groups are present on the backsheet or frontsheet to which the encapsulant will be laminated.

When the backsheet or frontsheet is modified, the functional groups incorporated onto the surface of the backsheet or frontsheet are specifically chosen based on the encapsulant and the functional groups already present on the backsheet/frontsheet. For example, when the encapsulant is a LLDPE containing less than 2% vinyl-trimethoxysiloxane, and the backsheet is selected from an AAA, TPT or KPK backsheet, the functionality introduced to the backsheet includes hydroxyl, carboxylic acid or silane/silanol. When the encapsulant is a LLDPE containing less than 2% vinyl-trimethoxysiloxane, and the frontsheet is an ETFE-containing frontsheet, the functionality introduced to the frontsheet includes hydroxyl, carboxylic acid or silane/silanol.

The introduction of functional groups or functional molecules to the surface of a backsheet, frontsheet or encapsulant improves covalent bonding between the film pairs. The improved covalent bonding increases the adhesion between the film pairs after lamination. However, the adhesion between film pairs may also be improved by increasing molecular diffusion between the film pairs.

In further embodiments, backsheets, frontsheets or encapsulants, preferably backsheets or frontsheets having a melting temperature greater than or equal to 150° C., may be modified to include a coating of functionalized polyolefins with a melting temperature below that used during lamination to increase molecular diffusion/welding. Exemplary functionalized polyolefins include EVA, ethylene acrylate copolymers, ethylene acid copolymers, chlorinated polyethylene, and polyethylene modified with functional groups such as maleic anhydride, amine, hydroxyl, carboxylic acid. In some embodiments, the same coating containing functional groups or functional molecules used to increase covalent bonding, as described above, may have a melting temperature below the lamination temperature. Such coatings will also serve to increase molecular diffusion.

The adhesion between a backsheet or frontsheet and encapsulant having a surface modification as described above is at least 20 N/cm, preferably at least 40 N/cm or no adhesion failure, before and after at least 1,000 hours, preferably 2,000 hours, of damp heat aging at 85° C. and 85% humidity.

Method of Improving Adhesion

In one embodiment, a method of improving the adhesion between a polyolefin-based encapsulant and a backsheet or frontsheet is provided. The polyolefin-based encapsulant is a polyethylene-based encapsulant and may include a minor amount of functionality. Preferably the polyolefin-based encapsulant is linear low density polyethylene (LLDPE) grafted with less than 2% vinyl-trimethylsiloxane.

The backsheets and frontsheets used in the practice of this method typically have limited functionalities on the surface and a seal layer with a high melting temperature (≧150 C). The backsheet/frontsheet is preferably selected from the group consisting of an AAA backsheet, a TPA backsheet, a FPA backsheet, an APA backsheet, a TPT backsheet, a KPK backsheet, an FPF backsheet, fluoropolymer-containing frontsheets (i.e., ETFE-, FEP-, and PVDF-containing frontsheets) and PET/PEN- and polyimide-containing frontsheets.

In an embodiment, a method of improving adhesion of a polyolefin-based encapsulant to a backsheet or frontsheet comprises the step of (A) modifying the surface of at least one of a backsheet, frontsheet or encapsulant. Preferably, the method for improving adhesion of a polyolefin-based encapsulant to a backsheet or frontsheet comprises the step of (A) modifying the surface of the backsheet or frontsheet. More preferably, the step of (A) modifying the surface of the backsheet or frontsheet comprises introducing specific at least one functional group or functional molecule to the surface of the backsheet or frontsheet to improve covalent bonding or molecular diffusion between the encapsulant and the surface-modified backsheet or frontsheet. The adhesion between an encapsulant and surface-modified backsheet or frontsheet is at least 20 N/cm, preferably at least 40 N/cm or no adhesion failure, before and after 1,000 hours, preferably 2,000 hours, of damp heat aging at 85° C. and 85% humidity.

In an embodiment, the step of (A) modifying the surface of a backsheet, frontsheet or encapsulant includes applying a functionalized coating to the backsheet, frontsheet or encapsulant. The coating may be applied using conventional coating methods or by introducing a functionalized layer to a backsheet, frontsheet or encapsulant by co-extrusion or thermal lamination. In an alternative embodiment, the step of (A) modifying the surface of a backsheet, frontsheet or encapsulant includes subjecting the backsheet, frontsheet or encapsulant to atmospheric plasma treatment to introduce at least one functional group or functional molecule to the surface of the film. Functionality can also be introduced to backsheets, frontsheets or encapsulants during production or manufacturing using functional materials.

In each of the above-described embodiments, the backsheet, frontsheet or encapsulant is modified to introduce a functional group or functional molecule to a surface of the film. In an exemplary embodiment, the functional group is selected from the group consisting of hydroxyl, silane/silanol, carboxylic acid, amine, ester, maleic anhydride, epoxy, and peroxide. In an embodiment, the functional molecule is selected from the group consisting of EVA, ethylene acrylate copolymers, ethylene acid copolymers, chlorinated polyethylene, and polyethylene modified with a maleic anhydride, amine, hydroxyl or carboxylic acid group.

In an embodiment, the step of (A) modifying the surface of a backsheet, frontsheet or encapsulant includes applying a coating to the surface of the backsheet, frontsheet or encapsulant. Exemplary coatings include at least one functional group selected from the group consisting of hydroxyl, silane, silanol, amino, epoxy, ester, carboxylic acid, maleic anhydride, peroxide and combinations thereof In other embodiments, the coating includes at least one functional molecule, such as a functionalized polyolefin. Exemplary functionalized polyolefins are selected from the group consisting of poly(ethylene vinyl acetate); ethylene acrylate copolymers; ethylene acid copolymers; chlorinated polyolefins; amino, hydroxyl, carboxylic acid and maleic anhydride modified polyolefins and combinations thereof.

In preferred embodiments, the backsheet or frontsheet is modified and selected from the group consisting of an AAA backsheet, an FPA backsheet, a TPA backsheet, an APA backsheet, a TPT backsheet, a KPK backsheet, a FPF backsheet, an EFTE-containing frontsheet, an FEP-containing frontsheet, a PVDF-containing frontsheet, a polyimide-containing frontsheet, and a PET/PEN frontsheet. Preferably, when the backsheet is modified, the backsheet is an AAA, TPT or KPK backsheet and surface modification is a functional group selected from the group consisting of a hydroxyl, carboxylic acid and silane/silanol group. When the frontsheet is modified, the frontsheet is preferably an ETFE-containing frontsheet and the functional group is selected from the group consisting of a hydroxyl, carboxylic acid and silane/silanol group.

The method of improving adhesion of a polyolefin-based encapsulant to a backsheet or frontsheet may also comprise the step of (B) laminating the encapsulant and backsheet or frontsheet to produce a laminated structure. The step of laminating is preferably completed at a temperature of 140-160° C. with 2-6 minutes of vacuum and 5-12 minutes of pressure.

A laminated structure having improved adhesion by the methods described herein will have an adhesion between the encapsulant and backsheet/frontsheet of at least 20 N/cm, preferably at least 40 N/cm or no adhesion failure. Preferably, the adhesion between the encapsulant and frontsheet or backsheet will be at least 20 N/cm, preferably at least 40 N/cm or no adhesion failure before and after 1,000 hours, preferably 2,000 hours, of damp heat aging at 85° C. and 85% humidity.

Functionalized Coatings

In an embodiment, the step of (A) modifying the surface of a backsheet, frontsheet or encapsulant includes applying a functionalized coating to the surface of the backsheet, frontsheet or encapsulant. Functionalized coatings increase the covalent bonding, molecular diffusion or both between the encapsulant and backsheet or frontsheet. A functionalized coating may be applied to only a single film (encapsulant, frontsheet or backsheet) or both films in the bonding pair. Preferably, the coating is applied to the surface of the backsheet or frontsheet.

In order to establish covalent bonding, the coating must include functional groups or functional molecules able to interact with those already present on the surface of the backsheet or frontsheet and encapsulant. For example, in embodiments where the backsheet is an AAA, TPT or KPK backsheet (or the frontsheet is an ETFE-containing frontsheet) and the coating is applied to the encapsulant, the coating includes amino groups, maleic anhydride groups, epoxy groups, carboxylic acid groups, ester groups or combinations of these groups. These groups interact with the ester, carboxylic acid, amine or fluorine groups already present on the surface of the AAA, TPT and KPK backsheets.

In some exemplary embodiments, the polyolefin-based encapsulant contains less than 2% vinyl-trimethylsiloxane, which can be crosslinked upon exposure to moisture. The only functional groups which may therefore be present in the encapsulant are —Si(OCH₃)₃ groups and hydrolysis products. In embodiments where the backsheet (i.e., AAA, TPT or KPK backsheet) or frontsheet (i.e., ETFE-containing frontsheet) is modified, the coating preferably includes hydroxyl groups, carboxylic acid groups, silane/silanol groups, or combinations of these groups. These groups interact with the small amount of functionality present on the encapsulant's surface.

In further exemplary embodiments, a coating applied to a backsheet or frontsheet may include functional molecules, such as functionalized silanes with an amino group or epoxy group. In other exemplary embodiments, a coating may include polyolefins functionalized with an amino group, epoxy group, maleic anhydride group, carboxylic acid group, chlorine, hydroxyl group, or combination thereof; ethylene acrylate copolymers; ethylene acid copolymers; and poly(ethylene vinyl acetate) copolymers which will not only increase covalent bonding, but also form strong welding bonds with the encapsulant during lamination because the melting temperature of the functional molecules is below that used for lamination.

In the exemplary embodiments described, the functionalized coating may be applied to a backsheet, frontsheet or encapsulant using any conventional coating method known in the art, such as spraying, draw down, rod, blade and curtain coating. The functionalized coating may also be incorporated as a layer of the encapsulant, backsheet or frontsheet by co-extrusion or thermal lamination. The coating may be applied to an overall thickness of 0.01 mil to 2 mil, more preferably 0.05 mil to 1 mil, even more preferably 0.1 mil to 0.5 mil.

According to an exemplary embodiment, the method of (A) modifying the surface of a backsheet, frontsheet or encapsulant includes (1) selecting a functionalized coating meeting at least one, preferably two, more preferably three and even more preferably all of the following criteria: (i) having functional groups which can form covalent bonds with the surface of the encapsulant and a backsheet or frontsheet, (ii) forming intermolecular welding with the encapsulant at the interface between the encapsulant and the backsheet or frontsheet during lamination, (iii) no blocking after coating and drying and during storage, and (iv) UV, thermal and moisture resistance to satisfy weatherability, thermal and damp heat age requirements for PV modules as defined in UL 1703 and IEC 61215; and (2) applying the functionalized coating to an encapsulant, backsheet or frontsheet to modify the surface of the encapsulant, backsheet or frontsheet. In preferred embodiments, the method of improving adhesion between a polyolefin-based encapsulant and a backsheet or frontsheet includes (2) applying the coating to the backsheet or frontsheet. The method may also include the step of (B) laminating the encapsulant to the backsheet or frontsheet.

In preferred embodiments, the coating is a functionalized polyolefin, or functionalized silane, meeting at least one, preferably two, more preferably three and even more preferably all of (i)-(iv) described above.

Preferably, the functionalized coating includes amino silane or an epoxy silane.

In one exemplary embodiment, the encapsulant comprises LLDPE with less than 2% silane functionality and the backsheet is either TPT or AAA (treated or untreated to include some functionality), and the method of improving adhesion between the backsheet and encapsulant includes (A) modifying the surface of the backsheet by (I) selecting a coating having an amino silane or epoxy silane, (2) applying the coating to the backsheet, and (B) laminating the backsheet and encapsulant.

Atmospheric Plasma Treatment

According to another embodiment, the step of (A) modifying the surface of a backsheet, frontsheet or encapsulant includes introducing specific functional groups to the surface of the backsheet, frontsheet or encapsulant using atmospheric plasma treatment to increase the covalent bonding between the encapsulant and backsheet or frontsheet. A gas mixture with functional molecules which vaporize during atmospheric plasma treatment is preferred to effectively introduce specific functional groups. In some embodiments, only one of the backsheet and encapsulant or frontsheet and encapsulant is subjected to atmospheric plasma treatment. In other embodiments, both the backsheet or frontsheet and encapsulant are subjected to atmospheric plasma treatment.

Atmospheric plasma treatment is the generation of a plasma discharge by electrical ionization of gases at atmospheric pressure. The gases include functional molecules, which vaporize and attach to a surface being treated. Atmospheric plasma treatment can also be used for surface cleaning and etching. Atmospheric plasma treatment offers unique advantages over existing technologies, such as corona treatment, including more uniform distribution of functional molecules, longer-lasting treatments, and higher levels of functional molecules introduced to a surface. Atmospheric plasma treatment also uses lower voltage than corona treatment, making it more efficient to use with difficult-to-treat materials, such as fluoropolymers, nonwoven materials, and foams. It is also easier to tailor the gas mixture used for atmospheric plasma treatment, allowing for more tailored modification of backsheet, frontsheet, and/or encapsulant surfaces.

In some embodiments, the method for improving adhesion between a polyolefin-based encapsulant and a frontsheet or backsheet by (A) modifying the surface of a backsheet, frontsheet or encapsulant by atmospheric plasma treatment includes the steps of (1) selecting a specific functional group to be introduced to the surface of an backsheet, frontsheet or encapsulant, and (2) subjecting the backsheet, frontsheet or encapsulant to atmospheric plasma treatment with functional molecules containing the functional group. Preferably, the backsheet or frontsheet is subjected to atmospheric plasma treatment. The method may also include the step of (B) laminating the encapsulant to the backsheet or frontsheet.

In some embodiments, the functional group meets at least one, preferably two, more preferably three and even more preferably all of the following criteria: (i) having functional groups which can form covalent bonds with the surface of the encapsulant and a backsheet or frontsheet; (ii) can be uniformly introduced to the surface of encapsulant, backsheet or frontsheet; (iii) the functionality will not significantly decay with time; and (iv) the resulting covalent bonds are UV, thermal and moisture resistant to satisfy weatherability, thermal and damp/heat age requirements for PV modules as defined in UL1703 and IEC 61215.

In preferred embodiments, the functional group is selected from the group consisting of hydroxyl, silane/silanol, carboxylic acid, amino and epoxy. More preferably, the film being modified is selected from the group consisting of an AAA backsheet, a TPT backsheet and a KPK backsheet and the functional group is selected from the group consisting of hydroxyl groups, silane/silanol groups, carboxylic acid groups and combinations thereof. In other embodiments, when the film being modified is a frontsheet, preferably an ETFE-containing frontsheet, the functional group is selected from the group consisting of hydroxyl groups, silane/silanol groups, carboxylic acid groups and combinations thereof. When the film being modified is a silane-grafted LLDPE encapsulant, the functional group is selected from the group consisting of carboxylic acid groups, amino groups, epoxy groups and combinations thereof. Preferably, the film being modified is an AAA backsheet, TPT backsheet, KPK backsheet or ETFE-containing frontsheet.

In an exemplary embodiment, the step of (1) selecting a functional group to be introduced to the surface of an backsheet, frontsheet or encapsulant may also include the step of selecting a gas mixture with functional molecules. Typically, an inert gas such as Ar, He, N₂ is used as the carrier gas. The carrier gas is mixed with gas combinations comprising the functional molecules. Simple gas combinations with O₂/H₂, CO₂, N₂/H₂, NH₃, and/or H₂O can be used to introduce OH, COOH and NH₂ functional groups. However, functional molecules with OH, COOH, NH₂, epoxy and silane groups which can vaporize in the gas stream are more preferable to the simple gas combinations. Such functional molecules include but are not limited to alcohols, amines, carboxylic acids, functional silanes. In a preferred embodiment, the gas mixture includes functionalized silane such as epoxy-silanes and amino silanes.

### EXAMPLES

Raw Materials

Dow Enlight encapsulant 66232 is a polyolefin-based encapsulant comprising linear low density polyethylene (LLDPE) grafted with less than 2% vinyl-trimethylsiloxane.

Icosolar AAA 3554 is a polyamide/polyamide/polyamide (AAA) tri-layer backsheet with a thickness of 350 um provided by Isovoltaic AG.

Icosolar 2442 TPT is a Tedlar/PET/Tedlar (TPT) tri-layer backsheet with a thickness of 350 um provided by Isovoltaic AG.

AKASOL PVL-1000V is a poly(vinylidene fluoride)/PET/poly(vinylidene fluoride) (KPK) tri-layer backsheet with a thickness of 330 um provided by Krempel.

Protekt HD is a fluoropolymer/PET/EVA tri-layer backsheet with a thickness of 249 um provided by Madico.

ETFE is a front sheet with a thickness of 50 um.

ADCOTE HS 33-193 is an EVA-based heat seal coating provided by Dow.

CPO 164 -1 is a chlorinated polyolefin with 18-23 wt % chlorine and a sating point of 80-105C provided by Eastman.

“Polyolefin dispersion” is a polyethylene dispersion with 50% solids provided by Dow.

Z-6020 silane is aminoethylaminopropyltrimethoxysilane provided by Dow Corning.

Z-6040 silane is glycidoxypropyltrimethoxysilane provided by Dow Corning.

Lamination Process

4 inch by 6 inch (102 mm×152 mm) glass laminates are prepared by a P-energy L200A Laminator for measuring adhesion of the encapsulant to the backsheet or frontsheet. The standard layout of the laminates was glass//(embossed side) front encapsulant (paper side)//(paper side) rear encapsulant (embossed side)//backsheet. A 4 inch by 4 inch (102 mm×102 mm) Teflon sheet is laid between the rear encapsulant and the backsheet or coated backsheet so that it can be removed after lamination to perform the peel test. When an ETFE frontsheet is used, the layout of the laminates is ETFE//(embossed side) front encapsulant (paper side)//(paper side) rear encapsulant (embossed side)//Protekt HD.

Lamination conditions were 160° C. with 3 minutes vacuum and 7 minutes pressure.

Testing Methods

Three 1 inch (25.4 mm) wide backsheet or frontsheet strips are cut from the 4 inch by 6 inch (102 mm×152 mm) laminate. The adhesion of encapsulants to backsheets and frontsheets is measured by 180° peel testing using an Instron at a speed of 2 inches per minute (50.8 mm/min). The adhesion after lamination is measured at 0 hours (initial adhesion), 500 hours, 1000 hours and 2000 hours of damp heat aging at 85° C. and 85% humidity.

Coatings

All coating formulations are coated on the backsheets using a 1 mil (25.4 microns) wire wound draw down rod followed by drying in a convection oven at 60° C. for 15 minutes. The thickness of the dried coating is 0.1 mil (2.54 microns) to 0.5 mil (12.7 microns).

Results

AAA backsheets are coated with compositions containing various functional groups. The coated backsheets are laminated with Enlight encapsulant as described above. The adhesion of Enlight to coated AAA backsheet is shown in Table 1.

TABLE 1
Adhesion of Enlight Encapsulant to Coated AAA Backsheet
Before and After Damp Heat Aging (DH)

| | | Adhesion of Enlight to Coated AAA | | | |
|---|---|---|---|---|---|
| | Coating | Backsheet (N/cm) | | | |
| | on AAA | | 500 hr | 1000 hr | 2000 hr |
| Examples | Backsheet | Initial | DH | DH | DH |
| Compar- | No coating | 47 | 14 | 2 | 2 |
| ative | | | | | |
| Example 1 | | | | | |
| Example 1 | ADCOTE | No | 27 | 23 | 20 |
| | HS 33-193 | adhesion | | | |
| | | failure | | | |
| Example 2 | CPO164-1 | No | 33 | 19 | 11 |
| | | adhesion | | | |
| | | failure | | | |
| Example 3 | Z-6020 | No | No | No | No |
| | amino-silane | adhesion | adhesion | adhesion | adhesion |
| | | failure | failure | failure | failure |
| Example 4 | Z-6040 | 96 | No | 37 | 29 |
| | epoxy-silane | | adhesion | | |
| | | | failure | | |

For Comparative Example 1, without any coatings, the initial adhesion of Enlight encapsulant to the AAA backsheet is around 47 N/cm with adhesion failure. However, after 500 hours of damp heat aging, the adhesion drops down to 14 N/cm. After 1000 and 2000 hours of damp heat aging, the adhesion is almost zero.

The adhesion of Enlight encapsulant to coated AAA backsheets (Example 1 to 4) before damp heat aging is significantly improved. Examples 1-3 failed due to backsheet destruction, such as backsheet tear or breakage, as indicated by “no adhesion failure.” No adhesion failure, or delamination between Enlight encapsulant and coated backsheet, is observed. After 500, 1000 and 2000 hours of damp heat aging, Examples 1 to 4 still have much higher adhesion than Comparative Example 1. Example 3 has no adhesion failure after 2000 hours damp heat aging.

TPT backsheets are also coated with compositions containing various functional groups. The TPT backsheets are laminated with Enlight encapsulant as described above. The adhesion of Enlight encapsulant to coated TPT backsheets before and after damp heat aging is shown in Table 2.

TABLE 2
Adhesion of Enlight Encapsulant to Coated TPT Backsheet
Before and After Damp Heat Aging (DH)

| | | Adhesion of Enlight to coated TPT | | | |
|---|---|---|---|---|---|
| | Coating | backsheet (N/cm) | | | |
| | on TPT | | 500 hr | 1000 hr | 2000 hr |
| Examples | Backsheet | Initial | DH | DH | DH |
| Compar- | No coating | No | 228 | 77 | 0 |
| ative | | adhesion | | | |
| Example 2 | | failure | | | |
| Example 5 | ADCOTE | 109 | No | No | 2 |
| | HS 33-193 | | adhesion | adhesion | |
| | | | failure | failure | |
| Example 6 | Polyolefin | No | No | No | 0 |
| | dispersion | adhesion | adhesion | adhesion | |
| | | failure | failure | failure | |
| Example 7 | Z-6020 | No | No | No | No |
| | amino-silane | adhesion | adhesion | adhesion | adhesion |
| | | failure | failure | failure | failure |
| Example 8 | Z-6040 | No | No | No | No |
| | epoxy-silane | adhesion | adhesion | adhesion | adhesion |
| | | failure | failure | failure | failure |

For Comparative Example 2 (no coating on the TPT backsheet), the initial adhesion is very good (no delamination between the Enlight encapsulant and the TPT backsheet is observed). However, after 500 hours of damp/heat aging, there is adhesion failure between the Enlight encapsulant and the TPT backsheet around 228 N/cm. The adhesion continues dropping down to 77 N/cm after 1000 hours of damp/heat aging and to zero after 2000 hours of damp heat aging.

Examples 5 to 8 show improved adhesion to Enlight encapsulant before and after damp heat aging. After 500 hours and 1000 hours of damp heat aging, no adhesion failure is observed in Examples 5 to 8, indicating better adhesion than Comparative Example 2. After 2000 hours damp heat, Examples 7 and 8 do not show adhesion failure.

In Examples 2 to 4 and 5 to 8 described above, all coatings act as a bridge between the Enlight encapsulant and the AAA or TPT backsheets. The functional groups in ADCOTE HS 33-193 (ester), chlorinated polyolefin CPE 164-1 (chlorine), polyolefin dispersion (carboxylic acid), Z-6020 (amine), and Z-6040 (epoxy) interact with the functional groups on the surface of AAA and TPT backsheets (ester, fluorine, amine, carboxylic acid) so that the coatings have a good adhesion to backsheet. In addition, ADCOTE HS 33-193, CPO-164-1 and polyolefin dispersions melt during lamination and lead to strong intermolecular welding with the Enlight encapsulant. The silane/silanol groups in Z-6020 and Z-6040 (Examples 3, 4, 7 and 8) form strong covalent bonding with the silane in Enlight encapsulant, resulting in the improved adhesion exhibited by Examples 3, 4, 7 and 8 even after 2000 hours of damp heat aging.

Atmospheric Plasma Treatment

Atmospheric plasma treatment is carried out using an Enercon 22″ tangential plasma system and plasma chemical vapor deposition (CVD). The surface energy of the backsheet or frontsheet after treatment is around 50-60 dyn/cm.

AAA backsheets and ETFE frontsheets are subjected to atmospheric plasma treatment to introduce selected functional groups to the surface of the backsheets/frontsheets. For comparative purposes, an AAA backsheet is also coronoa treated with air by a Corotec sheet-fed and roll-to-roll corona treating system. The corona or plasma treated AAA backsheets and treated ETFE frontsheets are shown in Table 3. The simple gas mixture of Ar/O₂ is used for the atmospheric plasma treatment of Comparative Example 4. The functional molecule epoxy silane (glicidoxypropyltrimethoxysilane) is introduced to the gas stream during the atmospheric plasma treatment of Examples 9 and 10. The adhesion of the treated AAA backsheets and ETFE frontsheets is given in Table 4.

TABLE 3
Atmospheric Plasma Treated Backsheet and Frontsheet

| Examples | Substrate | Carrier gas |
|---|---|---|
| Comparative Example 1 | AAA Backsheet | None (Used as Received) |
| Comparative Example 3 | AAA Backsheet | Air |
| Comparative Example 4 | AAA Backsheet | 90% Argon/10% O2 |
| Example 9 | AAA Backsheet | 96% Argon/4% H2 with |
| | | epoxy-silane |
| Comparative Example 5 | ETFE Frontsheet | None (Used as Received) |
| Example 10 | ETFE Frontsheet | 96% Argon/4% H2 with |
| | | epoxy-silane |

TABLE 4
Adhesion of Enlight Encapsulant to treated
AAA Backsheet and ETFE Frontsheet

| | Adhesion of Enlight to AAA Backsheet or | | | | |
|---|---|---|---|---|---|
| | ETFE Frontsheet (N/cm) NT = Not Tested | | | | |
| | Initial | 500 hr | 1000 hr | 2000 hr | 3000 hr |
| Examples | adhesion | DH | DH | DH | DH |
| Comparative | 47 | 14 | 2 | 2 | 2 |
| Example 1 | | | | | |
| Comparative | 16 | 24 | NT | NT | NT |
| example 3 | | | | | |
| Comparative | 49 | 39 | 4 | 4 | NT |
| Example 4 | | | | | |
| Example 9 | No | No | No | No | No |
| | adhesion | adhesion | adhesion | adhesion | adhesion |
| | failure | failure | failure | failure | failure |
| Comparative | No | No | 7 | NT | NT |
| Example 5 | adhesion | adhesion | | | |
| | failure | failure | | | |
| Example 10 | No | No | No | NT | NT |
| | adhesion | adhesion | adhesion | | |
| | failure | failure | failure | | |

When an AAA backsheet is treated with corona (Comparative Example 3), the initial adhesion to Enlight encapsulant is reduced to 16 N/cm. The AAA backsheet treated by atmospheric plasma with the simple gas mixture of 90% Ar/10% O2 (Comparative Example 4) shows no significant improvement in adhesion before and after damp heat aging. When AAA backsheet is treated by atmospheric plasma of 96% Ar/4% H2 with epoxy silane (Example 9), adhesion to Enlight encapsulants is dramatically improved—no adhesion failure or delamination between the Enlight encapsulant and treated AAA backsheet is observed. Example 9 fails by backsheet destruction, such as backsheet breakage, tear, or interlayer delamination, even after 3000 hours of damp heat aging.

Without plasma treatment (Comparative Example 5), the adhesion of the Enlight encapsulant to the ETFE frontsheet is only maintained after 500 hours of damp heat aging. With atmospheric plasma treatment with epoxy silane, the adhesion is maintained up to 1,000 hours of damp heat aging.

The above results indicate that corona treatment and simple atmospheric plasma treatment by a mixture of inert gas with O₂ is not effective to improve adhesion. Functional molecules with OH and silane/silanol groups, such as functional silanes and alcohols, must be used during atmospheric plasma treatment to introduce sufficient functional groups to establish enough interaction with the silane groups in Enlight encapsulants to further improve the adhesion.

1-13. (canceled)

14. A multilayer backsheet or frontsheet film comprising an outer seal layer with (a) a melting temperature greater than or equal to 150° C. and (b) at least one surface comprising at least one surface modification wherein the at least one surface with the at least one surface modification is configured to be in adhering contact with a polyolefin-based encapsulant film and wherein the adhesion of the multilayer film to the polyolefin-based encapsulant is at least 20 N/cm, wherein the outer seal layer is selected from the group consisting of a polyamide, a poly(vinyl fluoride), a poly(vinylidene fluoride), a polyimide and polyethylene terephthalate/polyethylene naphthalate.

15. The film of claim 14 wherein the adhesion is measured after damp heat aging at 85° C. and 85% humidity for at least 1,000 hours.

16. The film of claim 14 wherein the surface modification is a coating comprising at least one of a functional polyolefin or functional group.

17. The film of claim 16 wherein the functionalized polyolefin is selected from the group consisting of poly(ethylene vinyl acetate); ethylene acrylate copolymers; ethylene acid copolymers; chlorinated polyolefin; amino, hydroxyl, carboxylic acid and maleic anhydride modified polyolefins; and combinations thereof.

18. The film of claim 16 wherein the functional group is selected from the group consisting of hydroxyl, silane, silanol, amino, epoxy, ester, carboxylic acid, maleic anhydride, peroxide and combinations thereof.

19. The film or electronic device of claim 16 wherein the coating has no blocking after coating, drying and storage, and UV, thermal and moisture resistance satisfying the weatherability, thermal and damp heat age requirements defined in UL 1703 and IEC 61215.

20. The film of claim 14 wherein the surface modification is atmospheric plasma-applied functional molecules.

21. The film of claim 20 wherein the functional molecules are selected from the group consisting of alcohols, amines, carboxylic acids and functional silanes.

22. The film of claim 14 wherein the backsheet or frontsheet film is selected from the group consisting of an polyamide/polyamide/polyamide (AAA) backsheet, a poly(vinyl fluoride)/polyethylene terephthalate (PET)/polyamide (TPA) backsheet, an polyamide/PET/polyamide (APA) backsheet, a poly(vinyl fluoride)/PET/poly(vinyl fluoride) (TPT) backsheet, a poly(vinylidene fluoride)/PET/poly(vinylidene fluoride) (KPK) backsheet, poly(vinylidene fluoride) PVDF-containing frontsheets, polyimide-containing frontsheets, and a PET/polyethylene naphthalate frontsheets.

23. The film of claim 14 wherein the backsheet or frontsheet film is selected from the group consisting of a polyamide/polyamide/polyamide (AAA) backsheet, a poly(vinyl fluoride)/polyethylene terephthalate/poly(vinyl fluoride) (TPT) backsheet, and a poly(vinylidene fluoride)/polyethylene terephthalate/poly(vinylidene fluoride) (KPK) backsheet.

24. An electronic device comprising a polyolefin-based encapsulant and at least one of a multilayer backsheet or frontsheet, the backsheet or frontsheet having a seal layer comprising at least one surface comprising at least one surface modification which is in adhering contact with the encapsulant, wherein the adhesion between the backsheet or frontsheet and the encapsulant is at least 20 N/cm, and wherein the seal layer is selected from the group consisting of a polyamide, a poly(vinyl fluoride) a poly(vinylidene fluoride), a polyimide and polyethylene terephthalate/polyethylene naphthalate.

25. The electronic device of claim 24 wherein the adhesion is measured after damp heat aging at 85° C. and 85% humidity for at least 1,000 hours.

26. The electronic device of claim 24 wherein the surface modification is a coating comprising at least one of a functional polyolefin or functional group.

27. The electronic device of claim 26 wherein the functionalized polyolefin is selected from the group consisting of poly(ethylene vinyl acetate); ethylene acrylate copolymers;
ethylene acid copolymers; chlorinated polyolefin; amino, hydroxyl, carboxylic acid and maleic anhydride modified polyolefins; and combinations thereof.

28. The electronic device of claim 26 wherein the functional group is selected from the group consisting of hydroxyl, silane, silanol, amino, epoxy, ester, carboxylic acid, maleic anhydride, peroxide and combinations thereof.

29. The electronic device of claim 26 wherein the coating has no blocking after coating, drying and storage, and UV, thermal and moisture resistance satisfying the weatherability, thermal and damp heat age requirements defined in UL 1703 and IEC 61215.

30. The electronic device of claim 24 wherein the surface modification is atmospheric plasma-applied functional molecules selected from the group consisting of alcohols, amines, carboxylic acids and functional silanes.

31. The electronic device of claim 24 wherein the backsheet or frontsheet film is selected from the group consisting of an polyamide/polyamide/polyamide (AAA) backsheet, a poly(vinyl fluoride)/polyethylene terephthalate (PET)/polyamide (TPA) backsheet, an polyamide/PET/polyamide (APA) backsheet, a poly(vinyl fluoride)/PET/poly(vinyl fluoride) (TPT) backsheet, a poly(vinylidene fluoride)/PET/poly(vinylidene fluoride) (KPK) backsheet, poly(vinylidene fluoride) PVDF-containing frontsheets, polyimide-containing frontsheets, and a PET/polyethylene naphthalate frontsheets.

32. The electronic device of claim 24 wherein the backsheet or frontsheet film is selected from the group consisting of a polyamide/polyamide/polyamide (AAA) backsheet, a poly(vinyl fluoride)/polyethylene terephthalate/poly(vinyl fluoride) (TPT) backsheet, and a poly(vinylidene fluoride)/polyethylene terephthalate/poly(vinylidene fluoride) (KPK) backsheet.

33. A method of improving adhesion between a polyolefin-based encapsulant and at least one of a multilayer backsheet or frontsheet comprising an outer seal layer in an electronic device comprising the step of modifying a surface of the outer seal layer of the backsheet or frontsheet to introduce at least one functional molecule or functional group, wherein the functional molecule or functional group improves covalent bonding or intermolecular diffusion between the encapsulant and backsheet or frontsheet, and wherein the adhesion between the encapsulant and the surface-modified backsheet or frontsheet is at least 20 N/cm, wherein the outer seal layer is selected from the group consisting of a polyamide, a poly(vinyl fluoride), a poly(vinylidene fluoride), a polyimide, and polyethylene terephthalate/polyethylene naphthalate.
